(19) United States
(12) Patent Application Publication
(10) Pub. No.: US 2007/0022959 A1
(43) Pub. Date: Feb. 1, 2007

(54) Deposition apparatus for semiconductor processing

(76) Inventors: Craig Bercaw, Boulder Creek, CA (US); Dan Cossentine, Santa Cruz, CA (US); Robert Jeffrey Bailey, Scotts Valley, CA (US); Jack Chihchieh Yao, Scotts Valley, CA (US); Tommy Tsz-Kit Lo, Scotts Valley, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/496,787

(22) Filed: Jul. 31, 2006

Related U.S. Application Data
(60) Provisional application No. 60/703,711, filed on Jul. 29, 2005.
(60) Provisional application No. 60/703,717, filed on Jul. 29, 2005.
(60) Provisional application No. 60/703,723, filed on Jul. 29, 2005.

(51) Int. Cl. C23C 16/00

(52) U.S. Cl. 118/728

(57) ABSTRACT

The present invention relates generally to a deposition apparatus for semiconductor processing. More specifically, embodiments of the present invention relate to a deposition apparatus having a reduced reaction zone volume. In some embodiments a deposition apparatus is provided with a process chamber having a raised reaction zone. Other embodiments of the present invention provide a deposition apparatus with a process chamber having a vertical baffle ring. Embodiments of the present invention provide a reduced reaction zone or volume which promotes uniform gas flow pattern and faster gas exchange.

### CROSS REFERENCE TO RELATED APPLICATIONS

This application claims the benefit of, and priority to, U.S. Provisional Patent Application Ser. Nos. 60/703,711 filed on Jul. 29, 2005, 60/703,717 filed on Jul. 29, 2005 and 60/703,723 filed on Jul. 29, 2005, the entire disclosures of all of which are hereby incorporated by reference.

### FIELD OF THE INVENTION

The invention relates generally to deposition apparatus for semiconductor processing. More specifically, the invention relates to deposition apparatus having a reduced reaction zone or volume useful to perform various process methods to form thin films on a semiconductor substrate.

### BACKGROUND OF THE INVENTION

The manufacture of semiconductor devices requires many steps to transform a semiconductor wafer to an ensemble of working devices. Many of the process steps involve methods that are adapted to be practiced on one substrate at a time. These are known as single wafer processes. The process chambers used to practice these methods are known as single wafer chambers and should be distinguished from batch process chambers wherein a plurality of substrates may be processed simultaneously. Single wafer process chambers are often grouped together in a cluster tool that allows for the possibilities of either simultaneously practicing the same process methods on a number of substrates in parallel or practicing a number of process methods sequentially within the same cluster tool.

A number of process methods are well suited to be practiced in single wafer process chambers. Examples of these process methods include, but are not limited to: chemical vapor deposition (CVD), atomic layer deposition (ALD), physical vapor deposition (PVD), Epi, etching, ashing, rapid thermal processing (RTP), short thermal processes such as spike anneal, and the like. These methods often include an energy source to facilitate processing, particularly thermal processing. Examples of these energy sources comprise thermal, plasma, photonic, and the like. The detailed configuration of these various types of process chambers will be determined by the requirements of the process method and the desired result of the process step.

Cost of Ownership (COO) in dollars/wafer is a major consideration in the selection of semiconductor process equipment. The calculation of COO is very complex. One of the input variables is the uptime of the equipment. Uptime is dependent upon factors such as system reliability, time between manual cleans, manual clean time, requalification time, and the like. Most of the process methods cited above are practiced at elevated temperatures, low pressures, and require the exchange of several gaseous species during the various steps of the method. Therefore, details such as process chamber volume, process chamber materials, integration of energy sources, gas introduction means, exhaust means, and the like are critical in determining the success of the process method.

A process chamber design for the deposition of a thin film by Atomic Layer Deposition (ALD) will be used as an example. A substrate or wafer is typically supported on a substrate support and is heated to a temperature in the range of 100° C. to 600° C. A gas distribution apparatus, such as a showerhead injector, is placed above the substrate. The showerhead injector contains a plurality of holes to distribute gases across the surface of the wafer. A horizontal plate or ring is sometimes placed around the substrate support and loosely defines the bottom of the reaction volume. In such prior art systems this reaction volume is relatively large. The plate may contain a plurality of holes that allows the gas to be exhausted from the process chamber through a single exhaust port that is usually found in the lower portion of the process chamber, below the plane of the substrate. Additionally, it is common in the art for the plate to be located below the wafer transport plane. One major drawback of this configuration is that the slot valve and wafer transfer region through which the wafers are transported are also exposed to the reaction zone. This results in the deposition of materials, particles, and contaminants in the slot valve region. This also results in plasma field asymmetries for process methods that use a plasma energy source. Further, this wafer transfer region causes temperature non-uniformities during processing. The region tends to have a black body cavity effect and the area of the heater that is adjacent this region develops cold regions, thus causing uneven heating and processing of the wafer.

Thus, known process chamber designs suffer from a number of shortcomings. Reaction volumes tend to be excessively large relative to the volume of the cylinder defined by the diameter of substrate support. The walls of such process chambers are often not symmetrical due to the requirement for additional ports, substrate transfer openings and the like. Power from energy sources such as thermal, plasma, and photonic sources reach the walls of the process chamber and facilitate the actions of the process method outside the areas which are directly above the substrate. This leads to undesirable effects including one or more of: long evacuation times, excessive chemical usage, long purge times, long cycle times for ALD process methods, asymmetric gas flow, particle generation, asymmetric plasma densities for plasma process methods, material deposits on the walls of the process chamber, shorter times between cleaning the process chamber, and the like.

The details and specific configuration of the process apparatus and components, such as the reaction zone volume, substrate support, showerhead, plate, and the like will have a direct effect on the time required to heat the wafer, evacuate the process chamber, introduce and exhaust the various gases, and the like. In turn, all of these aspects will impact the throughput and productivity of the overall semiconductor process equipment.

Given the many limitations of known deposition apparatus designs, there is a need for further developments in the design of deposition apparatus and components suitable for semiconductor processing.

### BRIEF SUMMARY OF THE INVENTION

The present invention relates generally to a deposition apparatus for semiconductor processing. More specifically, embodiments of the present invention relate to a deposition apparatus having a reduced reaction zone volume. In some embodiments a deposition apparatus is provided with a process chamber having a raised reaction zone. Other embodiments of the present invention provide a deposition apparatus with a process chamber having a vertical baffle ring. Embodiments of the present invention provide a reduced reaction zone or volume which promotes uniform gas flow pattern and faster gas exchange. Embodiments of the present invention can minimize chamber contamination and facilitate easier chamber cleaning. Embodiments of the present invention promote more uniform temperature distribution to the wafer during processing.

In some embodiments, a deposition apparatus for processing a substrate is provided comprising a process chamber having a wafer support for holding a substrate; a wafer transfer region where the substrate is conveyed by a robot transfer device onto the wafer support through an opening in the wall of the process chamber; a gas distribution assembly positioned above the substrate; a baffle ring within the process chamber that separates a reaction volume from an exhaust volume; and the wafer support being movable in the direction toward the gas distribution assembly to raise the substrate above the level of the wafer transfer region and the opening in the wall of the process chamber and cooperates with the baffle ring to define a reaction zone having reduced volume.

In another aspect, embodiments of the present invention provide an apparatus comprising: a vertical baffle ring assembly used to define a reaction volume in a semiconductor process chamber, and a plurality of apertures through the walls of the baffle ring.

In some embodiments, a deposition apparatus for processing a wafer is provided, said deposition apparatus including an opening in a wall of the apparatus and a wafer transfer region where the wafer is transported in and out of the apparatus, characterized in that: said apparatus is configured during processing such that a reaction zone is formed by a gas distribution assembly, wafer support and a baffle ring encircling the wafer support, said reaction zone being isolated from the opening and the wafer transfer region.

In other embodiments a deposition apparatus is provided comprising a gas exhaust plenum encircling the substantial circumference of a baffle ring to form an annular exhaust space, said gas exhaust plenum being configured to exhaust gases from the reaction zone over substantially 360 degrees.

In further embodiments an ALD deposition apparatus for processing a wafer, comprising: a process chamber housing a wafer support; an injector for conveying gases to the wafer; a baffle ring encircling the wafer support, said wafer support, injector and baffle ring defining a reaction zone where the wafer is processed, said reaction zone being isolated from a region where the wafer is moved in and out of the process chamber; and a gas exhaust plenum encircling the baffle ring and in fluid communication with apertures formed in the baffle ring, said gas exhaust plenum being configured to exhaust gases from the reaction zone over substantially 360 degrees.

### BRIEF DESCRIPTION OF THE DRAWINGS

These and various other features and advantages of the present invention will be apparent upon reading of the following detailed description in conjunction with the accompanying drawings and the appended claims provided below, in which:

FIG. 1 is a cross section simplified view of one embodiment of the deposition apparatus of the present invention showing a wafer support in the down position;

FIG. 2 is a cross section simplified view of one embodiment of the deposition apparatus of the present invention showing a wafer support in the up position;

FIG. 3 is a three-dimensional cross-section view of a part of the deposition apparatus according to embodiments of the present invention; and

FIG. 4 is a three-dimensional exploded view of the deposition apparatus according to embodiments of the present invention.

### DETAILED DESCRIPTION OF THE INVENTION

The present invention relates in general to deposition apparatus for semiconductor processing. More specifically, embodiments of the present invention relate to a deposition apparatus having a reduced reaction zone volume. In some embodiments a deposition apparatus is provided with a process chamber having a raised reaction zone. Other embodiments of the present invention provide a deposition apparatus with a process chamber having a vertical baffle ring. Embodiments of the present invention provide a reduced reaction zone or volume which promotes uniform gas flow pattern and faster gas exchange. Embodiments of the present invention can minimize chamber contamination and facilitate easier chamber cleaning. Embodiments of the present invention promote more uniform temperature distribution to the wafer during processing.

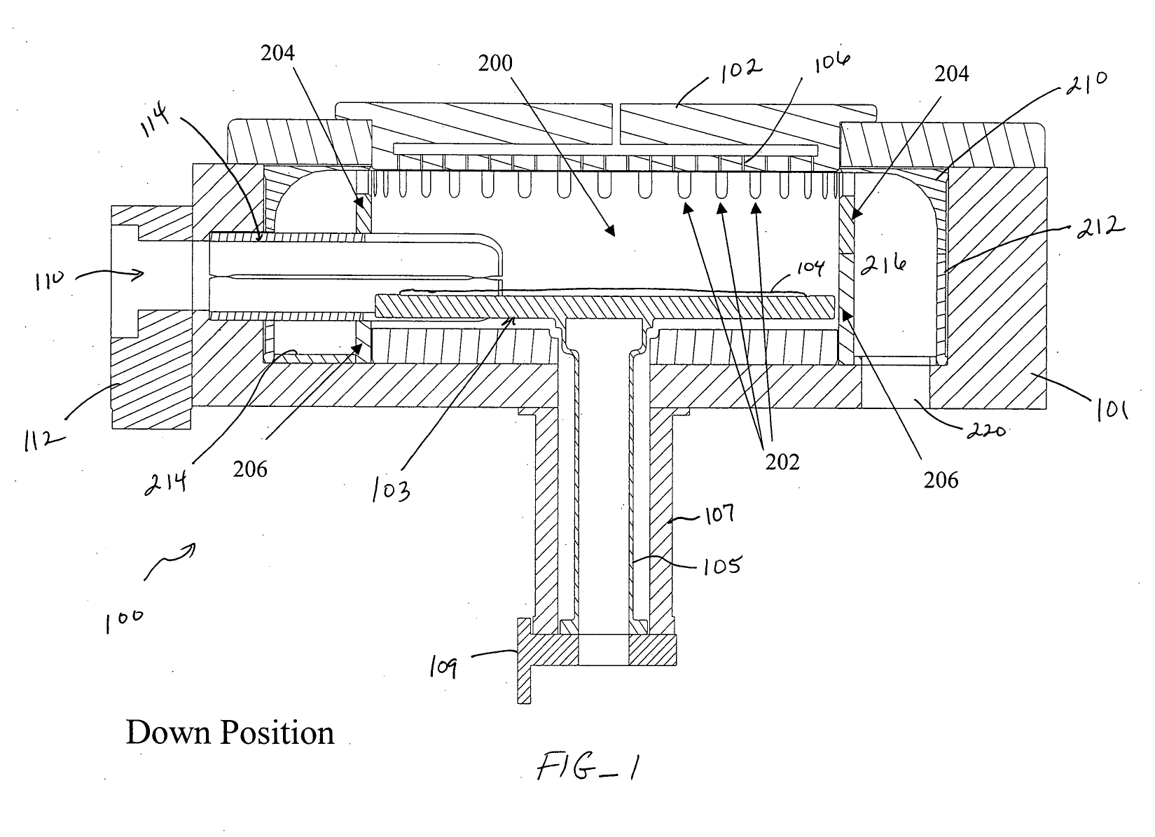

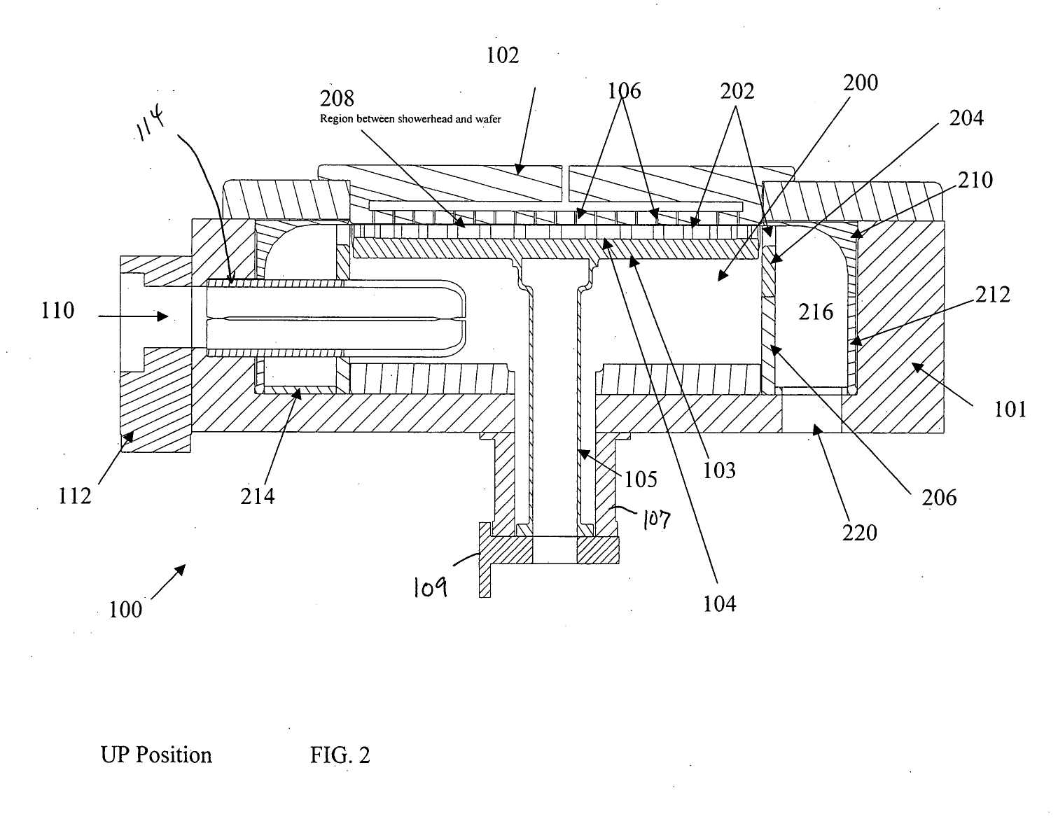

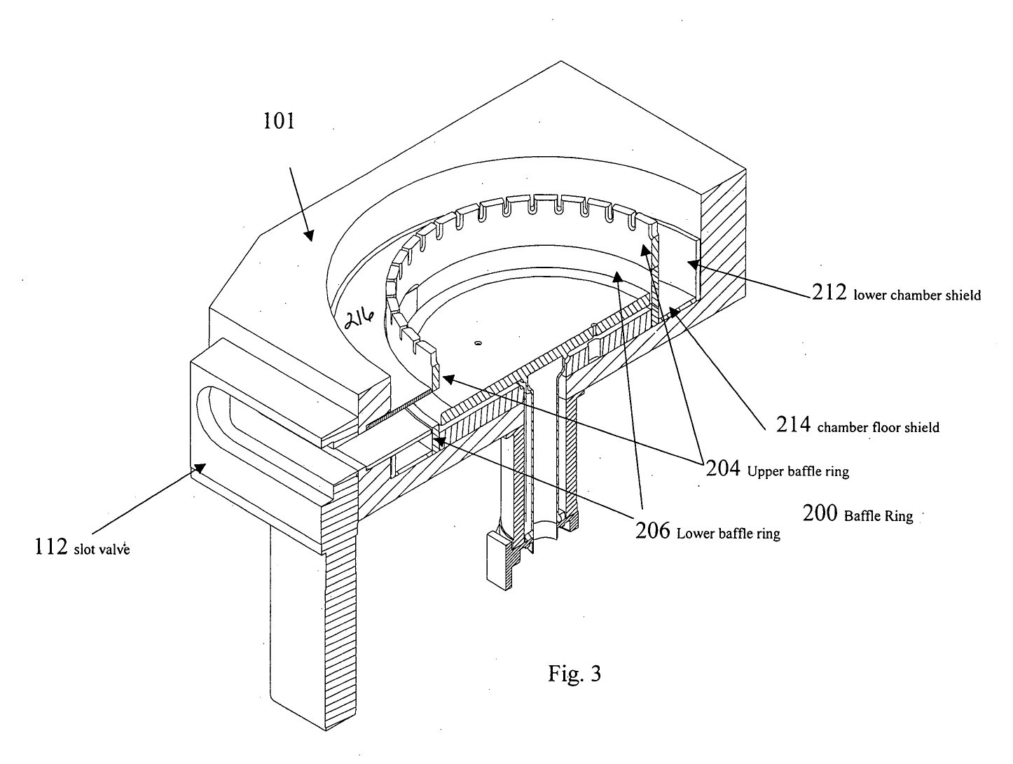

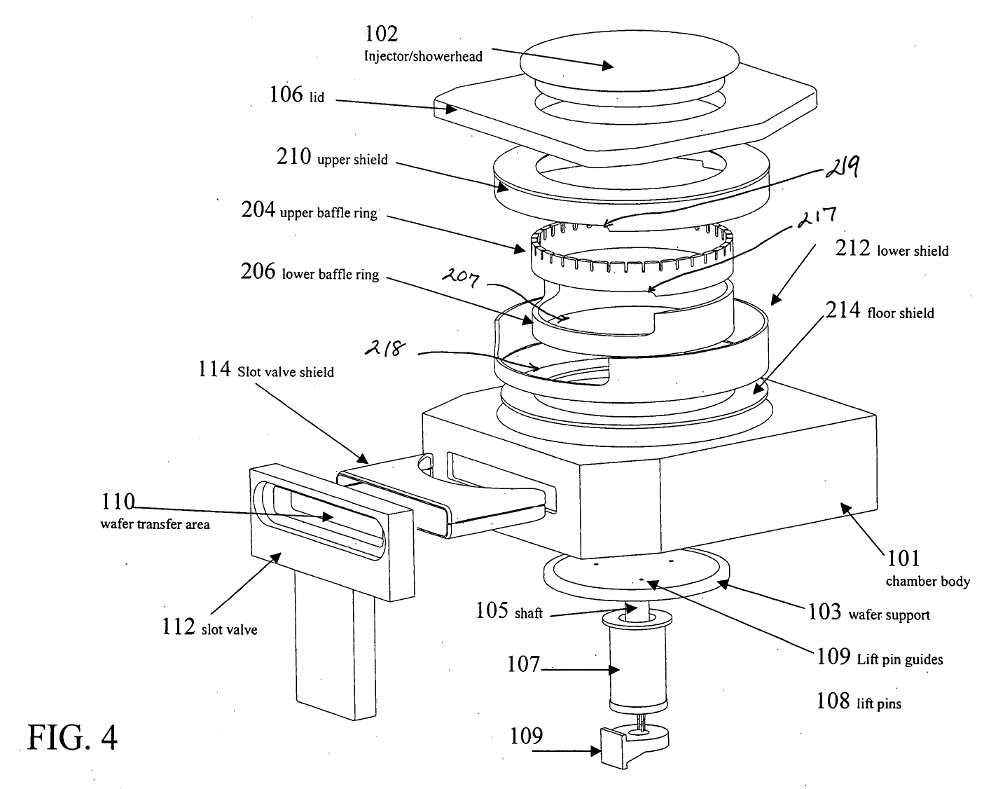

FIGS. 1 and 2 illustrate cross sectional simplified views of one embodiment of the deposition apparatus of the present invention. FIGS. 3 and 4 depict a partial three-dimensional cross-section view, and a three-dimensional exploded view, respectively, of embodiments of the deposition apparatus of the present invention. It will be appreciated by those skilled in the art that embodiments of the present invention may be applicable to carry out a wide variety of semiconductor processing methods such as chemical vapor deposition (CVD), atomic layer deposition (ALD), physical vapor deposition (PVD), Epi, etching, ashing, rapid thermal processing (RTP), short thermal processes such as spike anneal, and the like.

Referring to FIGS. 1 to 4, in general deposition apparatus 100 includes process chamber body or housing 101 that encloses a volume and includes a gas distribution device 102 for conveying gases to the chamber, wafer support 103 adapted to support a wafer or substrate 104 for processing, and baffle ring 200 encircling the wafer support 103, which together form a reaction zone or volume 208.

Typically a robotic transfer device (not shown) moves a wafer through a slot valve 112 through the wall of the process chamber 101 and into wafer transfer region 110. The wafer is placed on the wafer support 104, or on pins 108 protruding through wafer support 103. The deposition apparatus 100 is exhausted by a vacuum pump (not shown) through exhaust port 220.

Gases are introduced to deposition apparatus 100 through gas distribution assembly 102. Gas distribution assembly 102 may be comprised of any suitable gas delivery device; and may be comprised of for example: a single inlet, one or more injectors, a showerhead injector, a gas ring, or the like. Gas distribution assembly 102 may be powered depending on the requirements of the particular process method to be practiced. In an illustrative embodiment gas distribution assembly 102 is comprised of a showerhead type injector and includes a plurality of injector ports or orifices 106 spaced across a gas delivery surface of the injector. In another embodiment, gas distribution assembly 102 is comprised of an injector as described in U.S. Pat. No. 6,921,437, the entire disclosure of which is hereby incorporated by reference, which permits the delivery of two gases to the reaction zone 208 via independent gas distribution networks.

Gases are typically conveyed to gas distribution assembly 102 by one or more gas delivery lines (not shown). In one embodiment, gas delivery lines include a gas manifold valve cluster for fast deliver and actuation of gases, as described in detail in U.S. patent application Ser. No. ______ (Attorney Docket no. 186439/US/2/MSS and claiming priority to U.S. Provisional Patent Application Ser. No. 60/703,711), filed concurrently herewith, the entire disclosure of which is hereby incorporated by reference.

Wafer support 103 is configured to support wafer 104 during processing. Wafer support 103 generally includes a top surface having a pocket formed therein which receives and secures the wafer 104. Lift pin guides 109 (FIG. 4) may be formed in the wafer support for receiving lift pins 108. Lift pins 108 are typically extended above the surface of the wafer support to receive a wafer from a wafer transfer robot (not shown) and then retracted so that the wafer is seated in a pocket formed in the surface of wafer support 103 for processing. Lift pins 108 may be configured for independent movement. Alternatively, lift pins 108 may be stationary, and are extended and retracted by vertical movement of the wafer support 103.

The wafer support 103 may be heated and/or cooled via heater elements and/or cooling passages (not shown) formed in the body of the support. In some embodiments, wafer support 103 may be comprised of a stage heater. In other embodiments the wafer support may be comprised of an electrostatic chuck, and may be grounded or powered depending on the requirements of the particular process method to be practiced. Other energy sources may be provided, such as a plasma source, radiant heat lamps, UV source, and the like, and such other energy sources may be located at suitable locations within the deposition apparatus 100.

Of particular advantage, wafer support 103 is supported by a shaft assembly which is adapted to travel in the z-axis. The shaft assembly may also impart rotation to substrate support 103 if desired. In the exemplary embodiment shaft assembly is generally comprised of shaft 105 which is coupled to wafer support 103 and is actuated by sealed flexible bellows 107 and vertical motion coupler 109. While one particular embodiment of shaft assembly is shown, many other types of assemblies that provide z-axis travel may be used within the scope of the invention.

Z-axis travel of the shaft raises and lowers wafer support 103. FIG. 1 illustrates deposition apparatus 100 when the shaft 105 and wafer support 103 are in the down, or lower, position. FIG. 2 depicts deposition apparatus 100 when the shaft 105 and wafer support 103 in the up, or raised, position. In the exemplary embodiment flexible bellows 107 mates between the bottom of the process chamber 101 and vertical motion coupler 109. This placement permits changes in reaction zone volume 208 be changing the wafer support 103 height position within the process chamber, yet while maintaining an isolating seal between the outside atmosphere and the interior of the process chamber. According to embodiments of the present invention, deposition apparatus 100 is configured for processing when wafer support 103 and shaft 105 are in the raised position. When in the raised position as shown in FIG. 2, substrate support 103 cooperates with baffle ring 200 and gas distribution assembly 102 to define a reaction zone 208 having reduced volume. Notably, wafer transfer area 110 and slot valve 112 are not within the reduced reaction zone 208. Wafer transfer area 110 and slot valve 112 are below the wafer support 103, and thus do not impact the wafer 104 during processing.

During processing, this substantial reduction in the volume of reaction zone 208 promotes faster processing time since a much smaller volume must be exhausted between ALD pulse processing steps. Moreover, this reduced reaction zone promotes more uniform distribution of gases. Additionally, since transfer area 110, slot valve 112 and its associated slot valve shield 114 are below the wafer support 103, the wafer 104 is not subjected to black body effects nor is the heating and temperature uniformity disrupted, as is a common problem in prior art systems.

Of particular advantage, embodiments of the deposition apparatus of the present invention employ baffle ring 200. Since exhaust port 220 is usually at a single location in the bottom of process chamber 101, asymmetric gas flow in the reaction zone 208 may occur. Such asymmetric gas flow can lead to non-uniformities in the heating and deposition of films on the surface of the wafer during processing. Embodiments of the present invention address this problem. As illustrated in FIGS. 1 to 4, baffle ring 200 generally encircles the wafer support 103 and in the exemplary embodiment is comprised of an upper portion 204 and a lower portion 206. A plurality of baffle holes or orifices 202 are formed in the upper portion 204 of baffle ring 200. Baffle holes 202 allow unreacted or byproduct gases to flow from the reaction zone 208 into exhaust plenum 216. Baffle holes 202 are preferably spaced around the substantial circumference of the baffle ring 200 so to form an exhaust path for gases around the substantial to entire periphery of the wafer. This promotes substantially symmetric flow of gases from the wafer, and permits the exhausting of gases over 360 degrees.

Baffle holes 202 may be configured to be different sizes to compensate for the flow asymmetries in reaction volume 208 and/or to be tailored to specific applications and processes. In some embodiments, baffle holes 202 cause a flow restriction that creates a local pressure drop which promotes more uniform gas distribution across the wafer. Baffle holes 202 may be equally spaced around the substantial to entire circumference of the baffle ring 200. Alternatively, baffle holes 202 may be unequally spaced around the substantial to entire circumference of baffle ring 200 in order to selectively distribute the gases. The preferred number, geometric shape, size and distribution of baffle holes 202 may be selected based on the particular application or requirement of the process and may be determined by routine experimentation. Examples of suitable geometric shapes comprise slits, slots, rectangles, circles, triangles, trapezoids, and the like.

During processing, when the wafer support 103 is in the up, or raised position, the top surface of the wafer 104 is preferably positioned adjacent the baffle holes 202 to promote substantially symmetrical exhausting of unreacted gases and by-products. In one embodiment where the baffle holes are comprised of a slot, the top surface of the wafer is positioned adjacent the center-line of the bottom radius of the slot. Of course, other orientations are possible and are within the scope of the present invention.

The upper portion of baffle ring 200, also referred to as upper baffle ring 204, is made of a material comprising metals, metal alloys, ceramics, glasses, polymers, composites, or combinations thereof. The selection of the material will generally be driven by process requirements and cost of materials. Preferably, upper baffle ring 204 is composed of a ceramic. In some embodiments, top surface of upper baffle ring 204 mates with upper chamber shield 210 which is usually made of a similar material and serves to decrease the deposits of material on the lid 106 of deposition apparatus 100. Further, if a plasma process is used this configuration is useful in the confinement of the plasma density for plasma-based process methods. Upper baffle ring 204 is supported by the lower portion of the baffle ring 200, also referred to as lower baffle ring 206.

Lower baffle ring 206 has a slot or opening 207 that cooperates with substrate transfer area 110 to allow substrates to be transported into the process chamber of the deposition apparatus and placed on substrate support 103. This configuration allows lower baffle ring 206 to be manufactured from a less expensive material in those cases where upper baffle ring 204 is composed of an exotic, expensive material. Lower baffle ring 206 may be made from a material comprising metals, metal alloys, ceramics, glasses, polymers, composites, or combinations thereof. Preferably, lower baffle ring 206 is comprised of a simple metal, such as aluminum. In the exemplary embodiment, upper baffle ring 204 is shown as a simple cylinder, but the shape of upper baffle ring 204 may comprise cylinders, cones, polygons, or combination thereof.

In one embodiment of the present invention, the baffle ring assembly is made from 2 pieces, upper baffle ring 204, and lower baffle ring 206. Upper baffle ring 204, and lower baffle ring 206, may be made of the same material or may be made of different materials. Examples of the materials comprise metals, metal alloys, ceramics, glasses, polymers, composites, or combinations thereof.

In another embodiment of the present invention, the baffle ring 200 is made from a single piece formed by the fusion of upper baffle ring 204, and lower baffle ring 206. The single-piece baffle ring may be made of a variety of materials. Examples of the materials comprise metals, metal alloys, ceramics, glasses, polymers, composites, or combinations thereof.

In yet another embodiment of the present invention, baffle ring 200 is made from a single piece formed by the fusion of upper baffle ring 204 and lower baffle ring 206 and where upper shield 210 is been combined with the upper baffle ring 204 into a single part. The single-piece baffle ring assembly may be made of a variety of materials. Examples of the materials comprise metals, metal alloys, ceramics, glasses, polymers, composites, or combinations thereof.

Further, while the exemplary embodiments illustrated in the Figures show baffle ring 200 comprised of two pieces 204 and 206, either mated or fused, it should be understood that baffle ring 200 may alternatively be formed of a single ring.

Embodiments of the present invention provide for substantially symmetrical exhausting of gases from the deposition apparatus. Deposition apparatus 100 further includes gas exhaust plenum 216. Exhaust plenum 216 preferably is comprised of an annular space or channel that extends around the substantial circumference of the reaction zone 208 to promote symmetrical exhausting of gases from the reaction zone. In an exemplary embodiment, exhaust plenum 216 is formed by baffle ring 200 and a plurality of chamber shields, specifically upper chamber shield 210, lower chamber shield 212 and floor chamber shield 214 which are spaced apart from baffle ring 200 and which generally follow the general contour of baffle ring 200 to form there between an annular space. Gases exit the reaction zone 208 via baffle holes 202 and enter gas exhaust plenum 216, where the gases are then exhausted from the deposition apparatus 100 through vacuum pump port 220.

Chamber shields 210, 212, 214 and gas exhaust plenum 216 are shown in more detail with reference to FIGS. 3 and 4 which illustrate one exemplary embodiment of the present invention. Upper chamber shield 210 forms the top of exhaust plenum 216, and in some embodiments upper chamber shield 210 may abut the chamber lid 106 to form, in part with gas distribution assembly 102 the top of the reaction zone 208. Similar to the upper baffle ring 204 as described above, upper chamber shield 210 may be formed of specialized materials, particularly when upper chamber shield 210 is exposed to the reaction zone 208.

Lower chamber shield 212 generally forms the outer wall of exhaust plenum 216, while baffle ring 200 forms the inner wall of exhaust plenum 216. In one embodiment, lower chamber shield 212 has a slot or opening 218 that cooperates with substrate transfer area 110 to allow substrates to be transported into the deposition apparatus and placed on substrate support 103. Opening 218 in lower chamber shield 212 may have a similar contour and shape as opening 207 in lower baffle ring 206. Moreover, similar to lower baffle ring 206 as described above, lower chamber shield 212 may be formed of a different, and less expensive material, than upper chamber shield 210.

Opening 207 in lower baffle ring 206 and opening 218 in lower chamber shield 212 are adapted to receive slot valve shield 114 which permits the transfer of a wafer 104 in and out of the process chamber through the wafer transfer area 110, while maintaining isolation of the gas exhaust plenum 216. In some embodiments, upper baffle ring 204 and upper chamber shield 210 each also include an opening 217 and 219, respectively, which cooperate with the openings 207 and 218 in the lower baffle ring 206 and lower chamber shield 212 to accommodate the slot valve shield 114. Of particular advantage and in contrast to prior art apparatus, this permits the full, symmetrical exhausting of the gases over 360 degrees while isolating the reaction zone 208 from the wafer transfer region.

Chamber floor shield 214 generally forms the floor of exhaust plenum 216, and in the exemplary embodiment extends a full 360 degrees. Floor shield 214 may be comprised of any suitable material, and since it is not exposed to the reaction zone, floor shield 214 may be comprised of a different material than upper chamber shield 210.

As illustrated in the exemplary embodiment, chamber shields 210, 212 and 214 are formed of separate pieces. This allows for flexibility in material selection, and further allows for faster cleaning of the deposition apparatus since each of the shields may be removed and cleaned and/or serviced independently, without having to take the entire deposition apparatus 100 out of service. However, it should be understood that other embodiments are within the scope of the present invention. For example, in some embodiments all three shields may be formed of a single piece. Additionally, in another alternative embodiment, the lower chamber shield and chamber floor shield may be formed of a single piece.

The deposition apparatus of the present invention is particularly suited to carry out atomic layer deposition (ALD) processes. In general, ALD comprises conveying a first pulse of a precursor to the reaction zone where it forms a monolayer on the surface of the substrate. Excess amounts of the first precursor is then removed by techniques such as purging, evacuation, or combinations thereof. A next pulse of a reactant is then introduced and allowed to react with the monolayer of the first precursor to form the desired material. Excess amount of the reactant is then removed by techniques such as purging, evacuation, or combinations thereof. The result is the deposition of a single monolayer of the desired material. This sequence is repeated until the desired thickness of the target material has been deposited.

As described above, baffle ring 200, gas distribution assembly 102 and the wafer support 103 when in the raised position as illustrated in FIG. 2 all define a very small reaction volume 208 that has 360 degree symmetry and is void of any geometry required to accommodate the wafer transfer operation. This reduced reaction zone promotes one or more of: lower chemical usage, greater chemical efficiency, faster gas purge and evacuation times, faster gas exchange times, and the like. Embodiments of the present invention further promote higher throughput and lower cost of ownership for the semiconductor process equipment. Additionally, baffle ring 200 promotes confinement of an energy source, such as thermal energy or plasma energy, into reaction volume 208. This promotes fewer deposit build-up, lower particle contamination on the wafers, and increased time intervals between when the process chamber has to opened to be cleaned. Embodiments of the present invention also minimize the deposition of materials, by-products, or particles in the wafer transport area 110, since such area is not within the reduced reaction zone 208.

Experiments conducted using embodiments of the present invention exhibit lower chemical usage and uniformity. In one example, deposition of an aluminum oxide film Al₂O₃ was conducted by ALD from trimethyl aluminum (TMA) and water. Deposition rate was maintained while reducing the time and amount of precursors used to practice the method carried out in embodiments of the deposition apparatus of the present invention. Additionally, the uniformity of the deposited film is improved over prior art systems.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

We claim:

1. An apparatus for processing a substrate in a process chamber, comprising:
a wafer support for holding a substrate;
a wafer transfer region where the substrate is conveyed by a robotic transfer device through an opening in the wall of the process chamber and onto the wafer support;
a gas distribution assembly positioned above the substrate;
a baffle ring formed within the apparatus and encircling the wafer support and having a plurality of apertures formed therein, said baffle ring being configured to separate a reaction zone from an exhaust region; and
the wafer support being movable in the vertical direction toward the gas distribution assembly to raise the substrate above the level of the wafer transfer region and opening in the wall of the process chamber, and said wafer support cooperates with the baffle ring to define the reaction zone having reduced volume.

2. The apparatus of claim 1 wherein the baffle ring is comprised of an upper baffle ring and a lower baffle ring, and said plurality of apertures are formed in said upper baffle ring.

3. The apparatus of claim 1 wherein the shape of the baffle ring comprises a cylinder, a cone, a polygon, or a combination thereof.

4. The apparatus of claim 1 wherein the shape of the apertures comprises a slit, a slot, a rectangle, a circle, a triangle, a trapezoid, or a combination thereof.

5. The apparatus of claim 2 wherein the upper baffle ring and lower baffle ring are made of the same material.

6. The apparatus of claim 2 wherein the upper baffle ring and lower baffle ring are made of different materials.

7. The apparatus of claim 1 wherein the baffle ring assembly comprises a single part.

8. The apparatus of claim 1 further comprising: a gas exhaust plenum communicating with said apertures in said baffle ring to exhaust gases from the reaction zone.

9. The apparatus of claim 8 wherein said gas exhaust plenum encircles the substantial circumference of the baffle ring and is configured to exhaust gases from the reaction zone over substantially 360 degrees.

10. A deposition apparatus for processing a wafer, said deposition apparatus including an opening in a wall of the apparatus and a wafer transfer region where the wafer is transported in and out of the apparatus, characterized in that: said apparatus is configured during processing such that a reaction zone is formed by a gas distribution assembly, wafer support and a baffle ring encircling the wafer support, said reaction zone being isolated from the opening and the wafer transfer region.

11. The deposition apparatus of claim 10 further comprising an gas exhaust plenum encircling the substantial circumference of the baffle ring to form an annular exhaust space, said gas exhaust plenum being configured to exhaust gases from the reaction zone over substantially 360 degrees.

12. An ALD deposition apparatus for processing a wafer, comprising:
a process chamber housing a wafer support;
an injector for conveying gases to the wafer;
a baffle ring encircling the wafer support, said wafer support, injector and baffle ring defining a reaction zone where the wafer is processed, said reaction zone being isolated from a region where the wafer is moved in and out of the process chamber; and
a gas exhaust plenum encircling the baffle ring and in fluid communication with apertures formed in the baffle ring, said gas exhaust plenum being configured to exhaust gases from the reaction zone over substantially 360 degrees.
